(19) United States
(12) Patent Application Publication
(10) Pub. No.: US 2020/0347513 A1
(43) Pub. Date: Nov. 5, 2020

(54) EPITAXIAL WAFER PROCESSING METHOD

(71) Applicant: ZING SEMICONDUCTOR CORPORATION, SHANGHAI (CN)

(72) Inventors: Huajie Wang, Shanghai (CN); Lu Fei, Shanghai (CN); Gongbai Cao, Shanghai (CN); Chihhsin Lin, Shanghai (CN)

(21) Appl. No.: 16/840,800

(22) Filed: Apr. 6, 2020

(30) Foreign Application Priority Data
Apr. 30, 2019 (CN) 201910363973.4

(51) Int. Cl. C30B 25/02; H01L 21/02

(52) U.S. Cl. CPC C30B 25/02; H01L 21/02636; H01L 21/02664; H01L 21/02658

(57) ABSTRACT

This application provides an epitaxial wafer processing method, the processing method comprises providing an epitaxial wafer; measuring the flatness of the epitaxial wafer; performing vapor phase etching for the epitaxial wafer not meet the standard; growing epitaxial layer on the epitaxial wafer after the vapor phase etching. Compared with the traditional polishing rework process, the vapor phase etching for the epitaxial wafer of this application is much simpler and faster, therefore it can improve the production yield.

### CROSS-REFERENCE TO RELATED APPLICATIONS

This application claims priority to P.R.C. Patent Application No. 201910363973.4 titled “an epitaxial wafer processing method” filed on Apr. 30, 2019, with the State Intellectual Property Office of the People's Republic of China (SIPO).

### TECHNICAL FIELD

The present disclosure relates to semiconductor technology, and particularly, to an epitaxial wafer processing method.

### BACKGROUND

An epitaxial wafer is a basic material for the manufacture of integrated circuit (IC) devices. Epitaxial wafers usually use chemical vapor deposition methods to regenerate a layer of single crystal silicon film on polished silicon wafers to achieve improved control of the surface quality and conductivity of the silicon wafer.

The application of post-process components determines that more and more circuits and electronic components need to be fabricated on the wafer. With the development trend of integrated circuit designs towards light, thin, short, small, and power saving, the performance requirements of the chip are also becoming more stringent. Flatness is a major indicator of the performance of high-frequency ICs. High-end IC devices have strict requirements for flatness, and flatness improvement is one of the main research directions of silicon materials.

The epitaxial wafer flatness regulation is affected by two aspects of the epitaxial substrate and the epitaxial process. The flatness of the epitaxial substrate will directly affect the final performance. Generally, the flatness of the epitaxial substrate is tuned by a polishing process, and then the epitaxial substrates that meet the specifications are sorted and sent to the epitaxial station by a sorter for actual epitaxy. The epitaxial substrates that do not meet the specifications will be degraded to other low-level. The product may be returned to the polishing section for reprocessing, the process is more complicated, and it consumes production line capacity.

Therefore, it is necessary to propose a method for manufacturing epitaxial wafers to solve the above problems.

### SUMMARY

The method for manufacturing an epitaxial wafer provided by this application tunes the flatness of the epitaxial substrate by vapor phase etching. Compared with the traditional rework polishing method, the process is simple and fast, which can save production line productivity.

### BRIEF DESCRIPTION OF THE DRAWINGS

Exemplary embodiments will be more readily understood from the following detailed description when read in conjunction with the appended drawings, in which:

FIG. 1 shows a flowchart of a method for manufacturing an epitaxial wafer according to an embodiment of this application;

FIGS. 2A-2B respectively show thickness profile diagrams of epitaxial substrates before and after performing a vapor phase etching process in an embodiment;

FIGS. 3A-3B respectively show thickness profile diagrams of epitaxial substrates before and after a vapor phase etching process is performed under the condition that the etching time is 10 seconds in one embodiment;

FIGS. 4A-4B respectively show thickness profile diagrams of epitaxial substrates before and after a vapor phase etching process is performed under an etching time of 20 seconds in one embodiment;

FIGS. 5A-5B respectively show thickness profile diagrams of epitaxial substrates before and after a vapor phase etching process is performed under the condition that the etching time is 30 seconds in one embodiment.

### DETAILED DESCRIPTION

The embodiments of this application are described below by way of specific examples, and those skilled in the art can readily understand other advantages and effects of this application from the disclosure of the present disclosure. This application may be embodied or applied in various other specific embodiments, and various modifications and changes can be made without departing from the spirit and scope of the invention.

It should be understood that this application can be implemented in different forms and should not be construed as being limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity. The same reference numerals denote the same elements throughout.

It should be understood that when an element or layer is referred to as being “on”, “adjacent”, “connected to” or “coupled to” another element or layer, it can be directly on Other elements or layers are on, adjacent to, connected to, or coupled to other elements or layers, or intervening elements or layers may be present. In contrast, when an element is referred to as being “directly on”, “directly adjacent to”, “directly connected to” or “directly coupled to” another element or layer, there are no intervening elements or Floor. It should be understood that, although the terms first, second, third, etc. may be used to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below can be represented as a second element, component, region, layer or section without departing from the teachings of this application.

Spatial relation terms such as “below”, “above”, “on top of” etc. may be used herein for convenience of description to describe the relationship between one element or feature shown in the figure and other elements or features. It should be understood that in addition to the orientation shown in the figures, the spatial relationship terminology is intended to include different orientations of the device in use and operation. For example, if the device in the figures is turned over, then the element or feature described as “below” or “beneath” or “beneath” other elements or features would then be oriented “above” the other element or feature. Thus, the exemplary terms “below” and “below” can include both an orientation of above and below. The device may be otherwise oriented (rotated 90 degrees or otherwise) and the spatial descriptors used herein interpreted accordingly.

The terminology used herein is for the purpose of describing particular embodiments only and is not intended as a limitation of the invention. As used herein, the singular forms “a”, “an” and “the” are intended to include the plural forms as well, unless the context clearly indicates otherwise. It should also be understood that the terms “comprising” and/or “including”, when used in this specification, determine the presence of stated features, integers, steps, operations, elements and/or components, but do not exclude one or more other The presence or addition of features, integers, steps, operations, elements, parts, and/or groups. As used herein, the term “and/or” includes any and all combinations of the associated listed items.

Embodiments of the invention are described herein with reference to cross-sectional views that are schematic views of ideal embodiments (and intermediate structures) of the invention. As such, variations from the shapes shown can be expected due to, for example, manufacturing techniques and/or tolerances. Therefore, embodiments of this application should not be limited to the specific shape of the region shown here, but include shape deviations due to, for example, manufacturing. For example, an implanted region shown as a rectangle generally has round or curved features and/or implanted concentration gradients at its edges, rather than a binary change from the implanted region to the non-implanted region. Likewise, a buried area formed by implantation may result in some implantation in the area between the buried area and the surface through which the implantation proceeds. Thus, the regions shown in the figures are schematic in nature and their shapes are not intended to illustrate the actual shape of a region of a device and are not intended to limit the scope of the invention.

In order to thoroughly understand this application, a detailed structure will be proposed in the following description in order to explain the technical solution proposed by this application. The preferred embodiments of this application are described in detail below. However, in addition to these detailed descriptions, this application may have other embodiments.

Flatness is a major indicator of the performance of an epitaxial wafer. Its regulation is affected by both the epitaxial substrate and the epitaxial process. The flatness of the epitaxial substrate will directly affect the final performance. Generally, the flatness of the epitaxial substrate is first tuned by a polishing process, and then the epitaxial substrates that meet the specifications are sorted by a sorter and sent to the epitaxial station for actual epitaxy. The epitaxial substrates that do not meet the specifications will be degraded. Other low-end products may be returned to the polishing section for reprocessing, however, this method has lower production efficiency.

An embodiment of this application proposes a new processing method for an epitaxial substrate with unsatisfactory flatness, that is, a vapor phase etching process is used to improve the control. Compared with traditional rework polishing methods, vapor phase etching has a simpler and faster process, which can save production line productivity.

In order to thoroughly understand this application, detailed structures and/or steps will be proposed in the following description in order to explain the technical solution proposed by this application. The preferred embodiments of this application are described in detail below. However, in addition to these detailed descriptions, this application may have other embodiments.

### Exemplary Embodiment

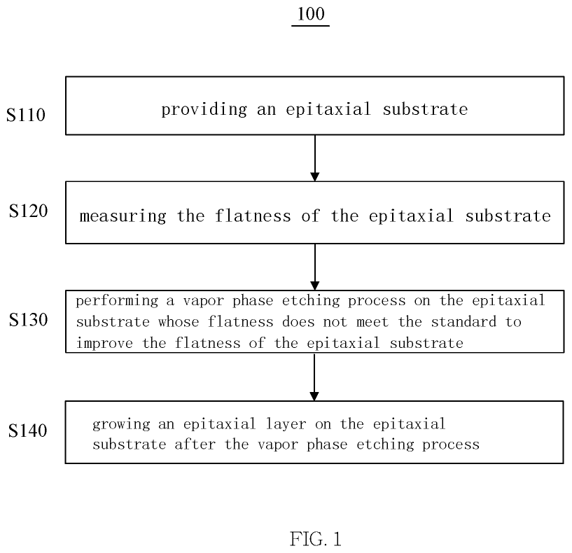

Hereinafter, a method for manufacturing an epitaxial wafer according to an embodiment of this application will be described in detail with reference to FIGS. 1, 2A, 2B to 5A, and 5B.

As shown in FIG. 1, first, in step S110, an epitaxial substrate is provided.

Wherein the epitaxial substrate may be a silicon wafer of any existing size. In one embodiment, the epitaxial substrate is a silicon wafer having a diameter of 300 mm.

As an example, the step of forming the epitaxial substrate includes: growing a single crystal silicon ingot in a single wafer epitaxial furnace; grinding and rounding the single crystal silicon ingot; and forming on the single crystal silicon ingot. Positioning edges or grooves to indicate a specific crystal orientation; slicing the single crystal silicon ingot at a predetermined angle to the axial direction; chamfering the surrounding portion of the silicon wafer obtained from the slicing to avoid chipping; and polish the silicon wafer. Exemplarily, the grinding includes sequential double-side grinding (DDSG) and single-side grinding (SDSG).

Next, the epitaxial substrate is polished, and the polishing may use an existing polishing process. For example, the polishing includes sequential double-sided polishing (DDSP) and single-sided polishing (SDSP). Exemplarily, after polishing, the method further includes the steps of cleaning and drying the epitaxial substrate, and the cleaning liquid used in the cleaning is, for example, ammonia water, hydrogen peroxide water, and deionized water.

In step S120, the flatness of the epitaxial substrate is measured.

Wherein the flatness performance of the epitaxial substrate may adopt SFQR (Site flatness front least-squares range), ESFQR (Edge Site flatness front least-squares range) Parameters, such as the least squares range in front), the global flatness back ideal range (GBIR), and the edge roll off (ERO). These parameters are mainly based on the thickness of the substrate to calculate. Specifically, a reference line is drawn in a predetermined area based on the measured thickness of the epitaxial substrate, and then a flatness parameter is calculated according to a maximum difference between the actual value and the reference line.

It can be understood that the above-mentioned parameters are only exemplary, and in addition to the above-mentioned parameters, other parameters or evaluation standards that can be used to test the flatness of the epitaxial substrate also fall within the protection scope of this application.

In step S130, a vapor phase etching process is performed on the epitaxial substrate whose flatness does not meet the standard.

Among them, existing epitaxial substrate classification standards can be used to screen out epitaxial substrates that do not meet the standards. For example, a sorting machine can be used to perform screening and classification according to the flatness parameter measured in step S120, select an epitaxial substrate that does not meet the standard, and perform the vapor etching process on it.

The vapor phase etching process is based on the fact that the etchant has different etching rates in different regions of the epitaxial substrate, thereby affecting the overall thickness and morphology of the epitaxial substrate and controlling it. In this embodiment, the etching gas used in the vapor phase etching process is HCl. When HCl is used as the etching gas, its etching rate is more suitable for regulating the thickness of the epitaxial substrate, and HCl is suitable for the existing epitaxial furnace. As an example, the vapor phase etching process may also use hydrogen as a carrier gas.

In one embodiment, the vapor phase etching process is performed based on a single wafer epitaxial furnace. The monolithic epitaxial furnace includes, but is not limited to, various types of monolithic epitaxial furnaces from manufacturers such as ASM and AMAT.

In the actual vapor phase etching process, the etching rate, etching time, etching temperature, and/or carrier gas flow rate can be tuned to achieve different etching rates in different regions, thereby obtaining an ideal thickness morphology. In one embodiment, when the etchant is HCl, the HCl etching flow rate is 1 slm-20 slm, such as 15 slm; the HCl etching time may be 1-50 seconds(s), such as 10 s, 20 s, or 30 s; the HCl etching temperature may be 1100° C.−1200° C., such as 1115° C.; the carrier gas (such as hydrogen) flow rate is 60 slm-120 slm, and the flatness of the substrate can be effectively tuned by using the above process conditions.

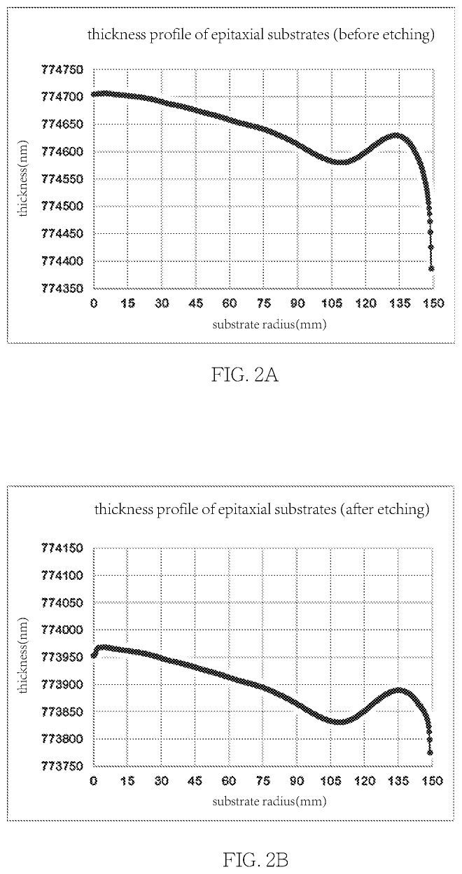

Referring to FIGS. 2A and 2B, there are respectively shown thickness profile diagrams of epitaxial substrates before and after a vapor phase etching process in an embodiment.

First, referring to FIG. 2A, a thickness profile of an epitaxial substrate having a flatness that does not meet the standard is shown. As shown in the figure, the ERO @ 148 mm of this substrate is −120 nm (the calculation method is: connect the thickness value at 120 mm to 140 mm, and the difference between the virtual thickness value and the actual thickness value obtained by extending this line to 148 mm is ERO @ 148 mm), and the standard range is −30 nm to −80 nm.

Next, referring to FIG. 2B, a thickness profile of the epitaxial substrate after the HCl vapor phase etching process is shown. The process parameters of the HCl vapor phase etching process are: an etching temperature is 1115° C., an etching time is 10 s, a flow rate of HCl is 15 slm, and a flow rate of a carrier gas (hydrogen) is 90 slm. As shown in the figure, after the above-mentioned HCl vapor phase etching treatment, the ERO @ 148 mm of the substrate is improved from −120 nm to −61 nm, falling within the standard range of −30 nm to −80 nm. After that, since the flatness of the epitaxial substrate is already within the standard range, an epitaxial layer can be grown on the epitaxial substrate without rework.

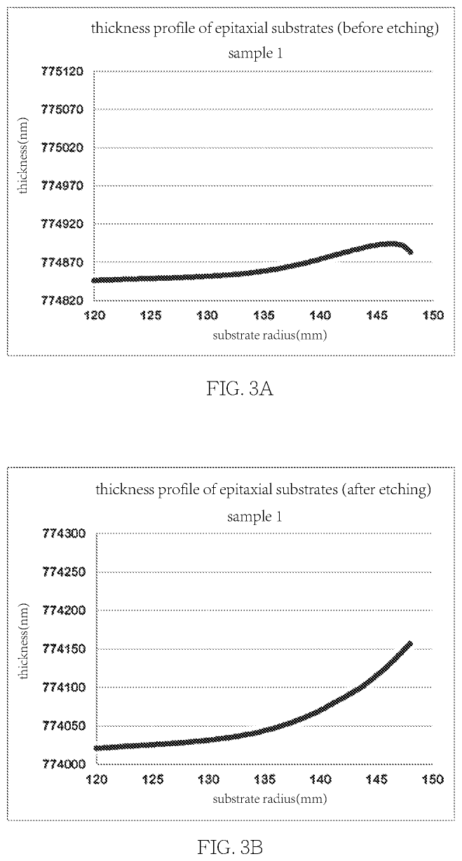

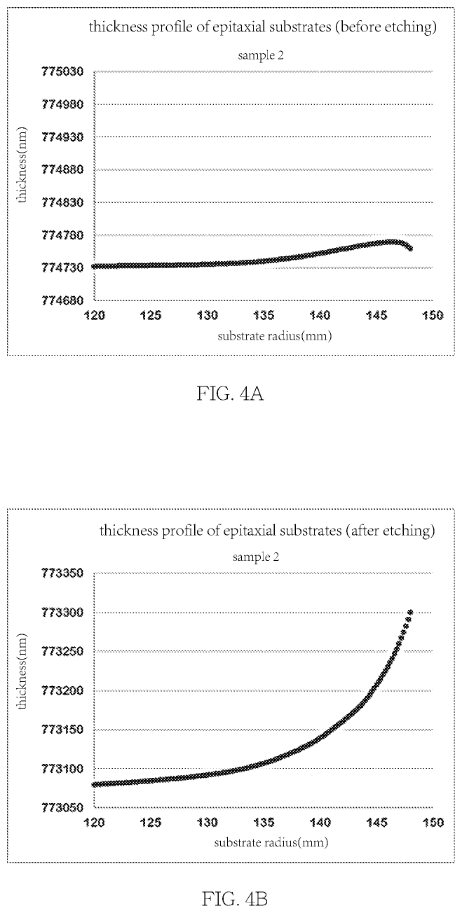

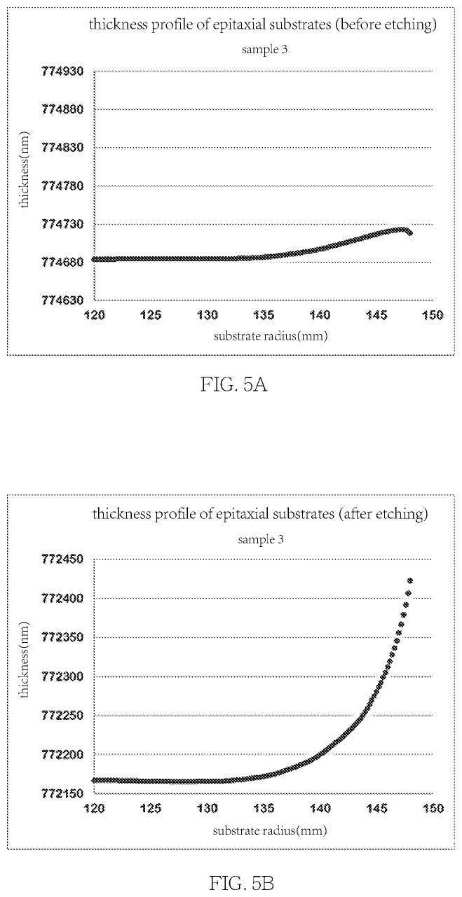

Referring to FIGS. 3A-5B, it is shown that when the etching temperature is 1115° C., the HCl flow rate is 15 slm, and the carrier gas (hydrogen) flow rate is 90 slm, the thickness profiles of a crystal substrate before and after etching for etching time is 10 s, 20 s, and 30 s, respectively. Referring to FIG. 3A and FIG. 3B, when the etching time is 10 s, the difference between the ERO @ 148 mm before and after the etching is 68 nm. Referring to FIG. 4A and FIG. 4B, when the etching time is 20 s, the difference between the ERO @ 148 mm before and after the etching is 138 nm. Referring to FIG. 5A and FIG. 5B, when the etching time is 30 s, the difference between the etched ERO @ 148 mm before and after the etching is 194 nm. It can be seen that the parameter value of ERO @ 148 mm can be tuned by tuning the etching time.

During the polishing process, because the substrate needs to be rotated, the polishing liquid is easily gathered on the edge of the wafer, which causes corrosion to the edge of the wafer, which in turn causes the thickness of the edge of the wafer to be thin. In the vapor phase etching process, the etching rate at the edge of the substrate is small, while the etching rate at the center of the substrate is large, and the difference between the two gradually becomes larger with time. Therefore, the thickness and morphology of the substrate can be tuned by tuning the etching time, reducing the thickness difference between the edge of the substrate and the center of the substrate, and planarizing the epitaxial substrate.

In step S140, an epitaxial layer is grown on the epitaxial substrate after the vapor phase etching process.

Among them, any suitable epitaxial method may be used to grow an epitaxial layer on the epitaxial substrate, and the epitaxial layer and the epitaxial substrate together form an epitaxial wafer. Since the flatness of the epitaxial substrate is controlled by the vapor phase etching process in step S130, the flatness of the epitaxial wafer finally formed can be improved.

In one embodiment, the epitaxial layer may be grown in the same monolithic epitaxial furnace. Specifically, the epitaxial substrate is placed on a rotating base in the reaction chamber of the monolithic epitaxial furnace, and is rotated by the rotating base. The monolithic epitaxial furnace is maintained at a normal pressure, and a reaction gas such as trichlorosilane and hydrogen is introduced into the reaction chamber at a preset epitaxial temperature to form an epitaxial crystal on the surface of the epitaxial substrate. Monocrystalline silicon film.

So far, the introduction of the relevant steps of the method for manufacturing an epitaxial wafer according to the embodiment of this application has been completed. It can be understood that the method for manufacturing an epitaxial wafer according to this embodiment includes not only the above steps, but also other required steps before, during, or after the above steps, which are all included in the scope of the manufacturing method of this embodiment.

In accordance with some embodiments, the vapor phase etching process is performed in a single wafer epitaxial furnace. The method for manufacturing an epitaxial wafer provided by this application tunes the flatness of the epitaxial substrate by vapor phase etching. Compared with the traditional rework polishing method, the process is simple and fast, which can save production line productivity.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. An epitaxial wafer processing method, comprising the steps of:
providing an epitaxial wafer;
measuring a flatness of the epitaxial wafer;
performing a vapor phase etching process for the epitaxial wafer not comply with a flatness standard to improve the flatness of the epitaxial wafer; and
growing an epitaxial layer on the epitaxial wafer after performing the vapor phase etching process.

2. The method according to claim 1, further comprising a step of polishing the epitaxial wafer prior to measuring the flatness of the epitaxial wafer.

3. The method according to claim 1, wherein the vapor phase etching process comprises HCl etching gas.

4. The method according to claim 1, wherein the flatness of the epitaxial wafer is tuned by controlling etchant gas flow rate, etching time, etching temperature and/or carrier gas flow rate of the vapor phase etching process.

5. The method according to claim 4, wherein the etching gas flow rate is in a range of 1˜20 slm.

6. The method according to claim 4, wherein the etching time is in a range of 1˜50 seconds.

7. The method according to claim 4, wherein the etching temperature is in a range of 1100˜1200° C.

8. The method according to claim 4, wherein the carrier gas of the vapor phase etching process comprises hydrogen.

9. The method according to claim 8, wherein the hydrogen flow rate is in a range of 60˜120 slm.

10. The method according to claim 1, wherein the vapor phase etching process is performed in a single wafer epitaxial furnace.
